(19) United States
(12) Patent Application Publication
(10) Pub. No.: US 2023/0123557 A1
(43) Pub. Date: Apr. 20, 2023

(54) SYSTEM AND METHOD FOR MODULAR AIR RECIRCULATION AND HEAT CAPTURE

(71) Applicant: Dell Products L.P., Round Rock, TX (US)

(72) Inventors: Eric Michael Tunks, Austin, TX (US); David L. Moss, Austin, TX (US); Ben John Sy, Austin, TX (US)

(21) Appl. No.: 17/451,221

(22) Filed: Oct. 18, 2021

(51) Int. Cl. H05K 7/20

(52) U.S. Cl. CPC H05K 7/20781; H05K 7/20745; H05K 7/20263

(57) ABSTRACT

A module modular containment system for isolating and cooling racks of information handling systems in a facility comprises a plurality of vertical panels coupled to a top panel to isolate the rack from room air and a heat exchanger coupled to a facility water feed that supplies water at a water temperature greater than the room air temperature. Heated air exiting the rack passes through the heat exchanger to transfer heat to the water such that the air is cooled to the first air temperature. An air conditioning system and the modular containment system can operate independently to cool the room air to a lower air temperature for the comfort of people in the facility and to cool information handling systems based on operating parameters of the information handling systems.

### BACKGROUND

### Field of the Disclosure

This disclosure relates generally to information handling systems and, more particularly, to modular systems for isolating information handling systems from a facility air conditioning system and cooling the information handling system with recirculated air and a facility water feed.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Datacenters are facilities that may have multiple rows of racks, with each rack having multiple information handling systems (servers) for processing information. Using the central air conditioning to cool information handling systems in the datacenter often results in high energy usage or an increased interior temperature.

### SUMMARY

Embodiments disclosed herein may be generally directed to modular systems for isolating information handling systems and cooling the information handling systems independently of room air in datacenters and other facilities in which the room air is maintained at a lower air temperature based on comfort of people working in the room.

Embodiments disclosed herein may be directed to a system for isolating and cooling information handling systems in racks in a facility, wherein the facility comprises an air conditioning system for maintaining room air at a room air temperature selected for the comfort of people working in the facility and air entering the information handling systems is at a first air temperature greater than the room air temperature, is heated by the information handling systems to a second air temperature greater than the first air temperature or the room air temperature, and is cooled back to the first air temperature to repeat the cycle.

Embodiments of a modular containment system may be configured to cool information handling systems in a rack in a facility having an air conditioning system for cooling room air to a room air temperature. The modular containment system comprises a top panel coupled to a plurality of vertical panels, wherein each vertical panel is coupled to an adjacent vertical panel to surround the rack and the vertical panels and the top panel isolate the rack from the room air. A heat exchanger is coupled to the back of the rack, and a conduit is coupled to the heat exchanger for supplying water at a first water temperature from a facility water feed. A first vertical panel of the plurality of vertical panels is positioned a first vertical panel separation distance from the heat exchanger and a second vertical panel of the plurality of vertical panels is positioned a second vertical panel separation distance from the front of the rack.

Air at a first air temperature flows into the front of the rack, wherein the air is heated to a second air temperature by the plurality of information handling systems. The heat exchanger transfers heat from the air that has been heated to the second air temperature by the plurality of information handling systems to the water such that the air is cooled to the first air temperature and the water is heated to a second water temperature. The plurality of vertical panels and the top panel channel air exiting the heat exchanger at the first air temperature to the front of the rack to repeat the cycle.

In some embodiments, the top panel is separated from a top of the rack by a top panel separation distance to allow air to flow over the rack. A third vertical panel that is coupled to the top panel, the first vertical panel and the second vertical panel is proximate a first side of the rack to prevent air flow around the first side of the rack. A fourth vertical panel that is coupled to the top panel, the first vertical panel and the second vertical panel is proximate a second side of the rack opposite the first side to prevent air flow around the second side of the rack, wherein the top panel, the first vertical panel and the second vertical panel channel the air exiting the heat exchanger over the rack.

In some embodiments, a modular containment system comprises a pass-through structure on top of the rack, wherein the top panel is proximate the pass-through structure. A third vertical panel that is coupled to the top panel, the first vertical panel and the second vertical panel is proximate a first side of the rack to prevent air flow around the first side of the rack. A fourth vertical panel that is coupled to the top panel, the first vertical panel and the second vertical panel is proximate a second side of the rack opposite the first side to prevent air flow around the second side of the rack, wherein the top panel, the pass-through structure, the first vertical panel and the second vertical panel channel the air exiting the heat exchanger through the pass-through structure over the rack.

In some embodiments, the top panel is proximate a top of the rack to prevent air flow over the top of the rack. A third vertical panel that is coupled to the top panel, the first vertical panel and the second vertical panel is separated from a first side of the rack by a third vertical panel separation distance that is less than half a width of the rack. The first vertical panel, the second vertical panel and the third vertical panel channel the air at the first air temperature around the first side of the rack. In some embodiments, a fourth vertical panel that is coupled to the top panel, the first vertical panel and the second vertical panel is separated from a second side of the rack opposite the first side by a third vertical panel separation distance that is less than half a width of the rack. The first vertical panel, the second vertical panel and the fourth vertical panel channel the air exiting the heat exchanger around the second side of the rack.

Embodiments may be directed to a modular containment system for cooling information handling systems in a row of racks in a facility having an air conditioning system for cooling room air to a room air temperature. A modular containment system may comprise a top panel separated from a top of each rack in a row of racks by a top panel separation distance and is coupled to a plurality of vertical panels. Each vertical panel is coupled to an adjacent vertical panel and the top panel to thermally isolate air exiting the row of racks from the room air. A heat exchanger is coupled to a back of each rack and a conduit coupled to each heat exchanger supplies water at a first water temperature from a facility water feed. A first vertical panel of the plurality of vertical panels is separated from the heat exchanger of each rack by a first vertical panel separation distance and a second vertical panel of the plurality of vertical panels is separated from a front of each rack by a second vertical panel separation distance. A third vertical panel is proximate a first side of a first rack in the row of racks and a fourth vertical panel is proximate a second side of a second rack in the row of racks, wherein the top panel, the first vertical panel and the second vertical panel channel the air exiting the heat exchangers over the first rack and the second rack to the front of each rack in the row of racks.

Embodiments may be directed to a modular containment system for cooling information handling systems in a row of racks in a facility having an air conditioning system for cooling room air to a room air temperature. A modular containment system may comprise a top panel separated from a top of each rack in a row of racks by a top panel separation distance. The top panel is coupled to a plurality of vertical panels and each vertical panel is coupled to an adjacent vertical panel and the top panel to thermally isolate air exiting the row of racks from the room air. A heat exchanger is coupled to a back of each rack and a conduit is coupled to each heat exchanger for supplying water at a first water temperature from a facility water feed. A first vertical panel of the plurality of vertical panels is separated from the heat exchanger of each rack by a first vertical panel separation distance and a second vertical panel of the plurality of vertical panels is separated from a front of each rack by a second vertical panel separation distance. A third vertical panel is proximate a first side of a first rack in the row of racks. A second rack adjacent the first rack may be separated from the first rack by a rack separation distance between a second side of the first rack and a first side of the second rack and a fourth vertical panel may be proximate a second side of the second rack in the row of racks such that the modular containment system channels the air exiting the heat exchangers between the first rack and the second rack to the front of each rack in the row of racks.

Embodiments may be directed to a facility comprising an air conditioning system for cooling room air to a room air temperature, a facility water feed for supplying water at a first water temperature, a plurality of racks in a plurality of rows of racks, each rack containing a plurality of information handling systems. A first row of racks may be oriented in a first direction and a second row of racks of the plurality of rows of racks may be oriented in a second direction opposite the first direction such that air exiting each rack of the first row of racks mixes with air exiting each rack of the second row of racks. A modular containment system for cooling the plurality of information handling systems separately from the air conditioning system comprises a top panel separated from a top of each rack by a top panel separation distance, wherein the top panel is coupled to a plurality of vertical panels to thermally isolate the plurality of rows of racks from an air conditioning system in the facility. A first vertical panel is separated from a front of each rack in the first row of racks by the first vertical panel separation distance, a second vertical panel is separated from a front of each rack in the second row of racks by the second vertical panel separation distance, a third vertical panel is proximate a first side of a rack on an end of each row, a fourth vertical panel is proximate a second side of a rack on an opposite end of each row. A heat exchanger is coupled to a back of each rack and a conduit is coupled to each heat exchanger for receiving water at a first water temperature from the facility water feed. Air at a first air temperature flows into the front of each rack, wherein the air is heated to a second air temperature by the plurality of information handling systems. The heat exchanger transfers heat from the air that has been heated to the second air temperature by the plurality of information handling systems to the water, wherein the air is cooled to the first air temperature and the water is heated to a second water temperature. The rack modular containment system channels a first portion of the air at the first air temperature in the first direction over the first row of racks and channels a second portion of the air at the first air temperature in the second direction over the second row of racks.

### BRIEF DESCRIPTION OF THE DRAWINGS

For a more complete understanding of the invention and its features and advantages, reference is now made to the following description, taken in conjunction with the accompanying drawings, in which:

FIG. 1 is a side view of a rack contained in one embodiment of a modular containment system;

FIG. 2 is a perspective view of a rack contained in one embodiment of a modular containment system configured for air circulation over a top of the rack;

FIG. 3 is a perspective view of a row of racks with a rack contained in one embodiment of a modular containment system configured for air circulation over a top of the row of racks;

FIG. 4 is a perspective view of multiple rows of racks contained in one embodiment of a modular containment system configured for air circulation over a top of each row of the plurality of rows of racks;

FIG. 5 is a perspective view of a rack contained in one embodiment of a modular containment system configured for air circulation around one or more sides of the rack;

FIG. 6 is a perspective view of a row of racks contained in one embodiment of a modular containment system configured for air circulation around one or more sides of one or more racks;

FIG. 7 is a perspective view of a rack contained in one embodiment of a modular containment system configured for air circulation through a pass-through structure on top of the rack;

FIG. 8 is a side view of a rack, illustrating a common approach to cooling a rack that requires an air conditioning system; and

FIG. 9 is a top view of a row of racks in a containment system that uses an in-row cooler.

### DESCRIPTION OF PARTICULAR EMBODIMENT(S)

In the following description, details are set forth by way of example to facilitate discussion of the disclosed subject matter. It should be apparent to a person of ordinary skill in the field, however, that the disclosed embodiments are exemplary and not exhaustive of all possible embodiments.

As used herein, a hyphenated form of a reference numeral refers to a specific instance of an element and the un-hyphenated form of the reference numeral refers to the collective or generic element. Thus, for example, rack “10-1” refers to an instance of a rack, which may be referred to collectively as racks “10” and any one of which may be referred to generically as rack “10.”

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and one or more video displays. The information handling system may also include one or more buses operable to transmit communication between the various hardware components.

Heat generated by components in information handling systems must be removed to prevent damage to the components or the information handling system. In individual information handling systems such as desktops and laptops, the amount of heat generated is generally low enough such that heated air leaving the information handling system can be cooled by a typical home air conditioning system. In some environments such as data centers, racks of multiple information handling systems continuously process large volumes of data and generate heat at a high rate such that an air conditioning system may be overburdened.

Embodiments of a modular containment system disclosed herein may thermally isolate one or more racks of information handling systems such that heated air exiting the information handling systems in each rack does not mix with room air (i.e., air cooled by a central air conditioning system), and the modular containment system may cool the heated air with water supplied by a facility water feed instead of chilled water such that modifications to a facility are not needed to accommodate more information handling systems.

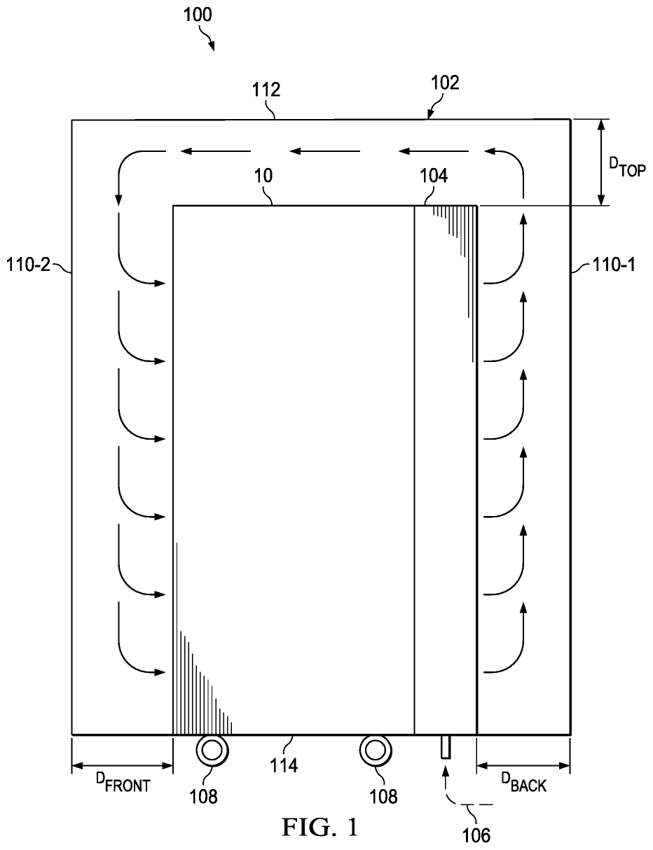

Particular embodiments are best understood by reference to FIGS. 1-9, wherein like numbers are used to indicate like and corresponding parts.

Turning to the drawings, FIG. 1 depicts a side view of one embodiment of modular containment system 100 encompassing rack 10 having a plurality of information handling systems (not shown). Modular containment system 100 comprises a plurality of vertical panels 110 and top panel 112 for thermally isolating rack 10. Modular containment system 100 further comprises heat exchanger 104 and conduit 106 coupled to a facility water feed (not shown) for cooling information handling systems in rack 10.

Panels Isolate a Rack to Prevent Heated Air from Mixing with Room Air

Each vertical panel 110 may be coupled to other vertical panels 110 to surround rack 10, and each of the plurality of vertical panels 110 is coupled to top panel 112 for thermally isolating rack 10 such air heated exiting information handling systems does not mix with room air being cooled by an air conditioning system.

Throughout this disclosure, the term “front” is used to describe a part of rack 10 in which air at a first air temperature enters rack 10, the term “back” is used to describe a part of rack 10 in which air at a second air temperature exits rack 10, and the term “side” is used to describe a part of rack 10 in which air generally does not enter or exit rack 10. Thus, air enters the front of rack 10 and exits the back of rack 10.

As used herein, first vertical panel 110-1 refers to a vertical panel 110 separated from heat exchanger 104 by a first vertical panel separation distance (D_{BACK}) and second vertical panel 110-2 refers to a vertical panel 110 separated from the front of rack 10 by a second vertical panel separation distance (D_{FRONT}). Third vertical panel 110-3 and fourth vertical panel 110-4 refer to vertical panels 110 that may be positioned proximate a rack 10 (including contacting rack 10 or otherwise preventing airflow around a side of rack 10) or separated from a side of rack 10 by a third (or fourth) separation distance to allow airflow around a side of rack 10), discussed in greater detail below. Although not shown, one or more of first vertical panel 110-1 and second vertical panel 110-2 may be hinged or include an access panel to allow a user to access rack 10 and information handling systems in rack 10.

In some embodiments, modular containment system 100 may also comprise bottom panel 114 coupled to vertical panels 110 for preventing heated air exiting rack 10 from mixing with the room air. In some embodiments, wheels or other supports 108 may be coupled to bottom panel 114 to thermally isolate rack 10. In other embodiments, bottom panel 114 is not present and vertical panels 110 may be coupled to a floor or other surface for preventing heated air exiting information handling systems from mixing with the room air.

Vertical panels 110 and top panel 112 (and bottom panel 114, if present) thermally isolate rack 10 such that air that is heated due to passing through rack 10 does not mix with room air cooled by a central air conditioning system.

Embodiments of modular containment system 100 further comprise heat exchanger 104 for receiving water at a first water temperature via conduit 106 and transferring heat from the air exiting rack 10 to the water. Conduit 106 may be coupled to an external cooling system separate from an air conditioning system used to cool the room air. The first water temperature may be higher than the room air temperature. Air at a first temperature (e.g., 91 F/33 C) may enter a front of rack 10 and be heated to a second air temperature (e.g., 115 F/46 C) and heat exchanger 104 may transfer heat from the air to the water to cool the heated air to the first air temperature (e.g., 91 F/33 C).

In a test case, modular containment system 100 was configured to thermally isolate a plurality of information handling systems in rack 10. Air entering rack 10 at a first air temperature of approximately 91 F/33 C was heated by the information handling systems to a second air temperature of approximately 117.3 F/47.4 C. A facility water feed supplied water at a first water temperature of approximately 86 F/30 C and heat exchanger 104 transferred heat such that air exiting heat exchanger 104 was cooled to the first air temperature 91 F/33 C before returning to flow through information handling systems in rack 10.

Thus, an air conditioning system may cool room air to a room air temperature (e.g., 70 F/23 C) for the comfort of persons working in the data center and modular containment system independently cools the information handling systems in rack 10.

In some embodiments, each information handling system has a set of fans that generate airflow through the information handling system and these fans may operate to ensure air enters the front of rack 10, flows through rack 10 to remove heat from information handling systems in rack 10, flows through heat exchanger 104 to a back of rack 10 and flows around or over rack 10 to the front of rack 10 to repeat the cycle.

### Directing Air Flow Over the Top of a Rack

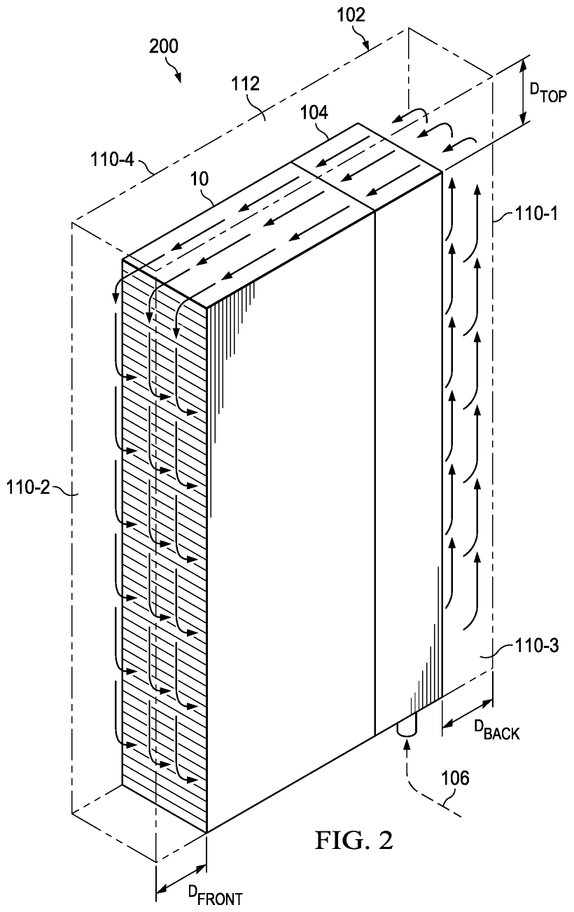

Turning to FIG. 2, a facility may have a rack 10 containing multiple information handling systems. In some embodiments, the facility may have an air conditioning system (not shown) for cooling room air to a room air temperature based on comfort of people working in the facility. Modular containment system 200 may be configured with a plurality of vertical panels 110-1 to 110-4 to thermally isolate a rack 10 and direct air to flow over the top of rack 10. First vertical panel 110-1 of the plurality of vertical panels 110 is positioned a first vertical panel separation distance (D_{BACK}) from heat exchanger 104, second vertical panel 110-2 of the plurality of vertical panels 110 is positioned a second vertical panel separation distance (D_{FRONT}) from the front of rack 10 and top panel 112 is positioned a top panel separation distance (D_{TOP}) above rack 10. Third vertical panel 110-3 and fourth vertical panel 110-4 are each coupled to first vertical panel 110-1 and second vertical panel 110-2 and top panel 112 and further proximate sides of rack 10. In this configuration, air at a first air temperature flows into the front of rack 10, the air is heated to a second air temperature by information handling systems in rack 10, the heated air exits rack 10 and flows through heat exchanger 104. Heat exchanger 104 receives water at a first water temperature and transfers heat from the air to the water to cool the heated air to the first air temperature. The air at the first air temperature exits heat exchanger 104, wherein third vertical panel 110-3 and fourth vertical panel 110-4 prevent the air from flowing laterally and first vertical panel 110-1, top panel 112 and second vertical panel 110-2 ensure the air flows over the top of rack 10 to the front of rack 10 to repeat the cycle.

### Modular Containment of a Rack in a Row of Racks

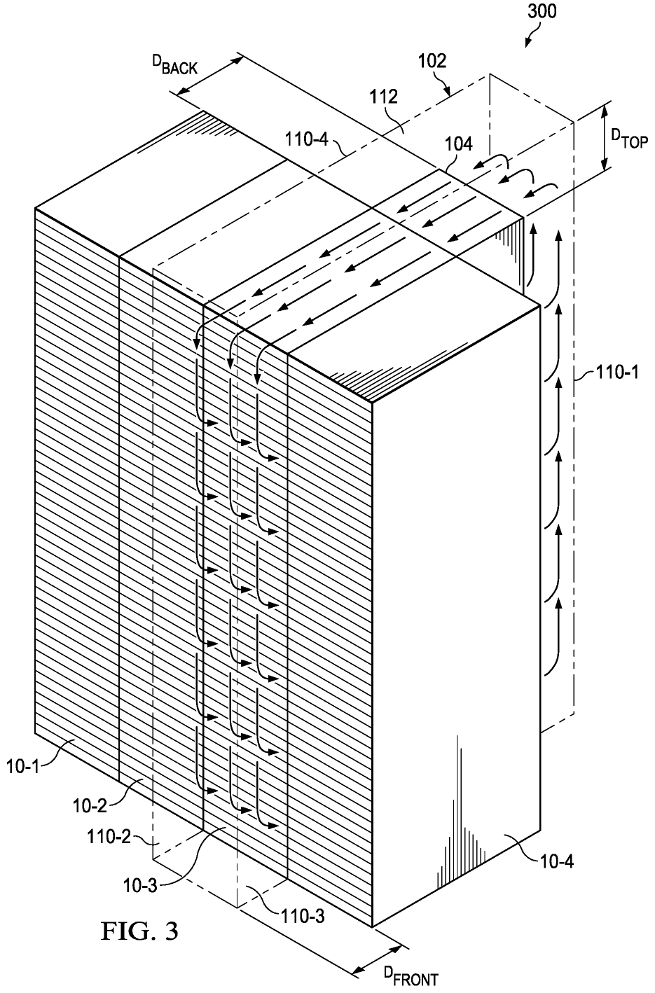

Turning to FIG. 3, in some embodiments, modular containment system 300 may be configured with a plurality of vertical panels 110-1 to 110-4 to thermally isolate a rack 10 (e.g., rack 10-3) in a row of racks 10 (e.g., racks 10-1 to 10-4) and direct air to flow over the top of the rack 10. First vertical panel 110-1 of the plurality of vertical panels 110 is positioned a first vertical panel separation distance (D_{BACK}) from heat exchanger 104, second vertical panel 110-2 of the plurality of vertical panels 110 is positioned a second vertical panel separation distance (D_{FRONT}) from the front of rack 10 and top panel 112 is positioned a top panel separation distance (D_{TOP}) above the row of racks 10. Third vertical panel 110-3 and fourth vertical panel 110-4 are each coupled to first vertical panel 110-1 and second vertical panel 110-2 and top panel 112 and further proximate sides of rack 10 (e.g., between racks 10-2 and 10-3 and between racks 10-3 and 10-4). In this configuration, air at a first air temperature flows into the front of rack 10-3, the air is heated to a second air temperature by information handling systems in rack 10-3, the heated air exits rack 10-3 and flows through heat exchanger 104. Heat exchanger 104 receives water at a first water temperature and transfers heat from the air to the water to cool the heated air to the first air temperature. The air at the first air temperature exits heat exchanger 104, wherein third vertical panel 110-3 and fourth vertical panel 110-4 prevent the air from flowing laterally and first vertical panel 110-1, top panel 112 and second vertical panel 110-2 ensure the air flows over the top of rack 10-3 to the front of rack 10-3 to repeat the cycle.

### Modular Containment of a Row of Racks

Referring to FIGS. 2 and 3, embodiments of modular containment system may be configured with a plurality of vertical panels 110-1 to 110-4 to thermally isolate a row of racks 10 or a portion of a row of racks 10 and direct air to flow over the top of the row of racks 10. First vertical panel 110-1 of the plurality of vertical panels 110 is positioned a first vertical panel separation distance (D_{BACK}) from heat exchangers 104 coupled to each rack 10 being thermally isolated, second vertical panel 110-2 of the plurality of vertical panels 110 is positioned a second vertical panel separation distance (D_{FRONT}) from the front of each rack 10 being thermally isolated and top panel 112 is positioned a top panel separation distance (D_{TOP}) above each rack 10. Third vertical panel 110-3 and fourth vertical panel 110-4 are each coupled to first vertical panel 110-1 and second vertical panel 110-2 and top panel 112. Third vertical panel 110-3 may be proximate a first side of a rack 10 on one end of the row of racks 10 being isolated. Fourth vertical panel 110-4 may be proximate a second side of a rack 10 on an opposite end of the row of racks 10 being isolated.

In this configuration, air at a first air temperature flows into the front of each rack 10 in the row of racks 10, the air is heated to a second air temperature by information handling systems in each rack 10, the heated air exits each rack 10 and flows through a heat exchanger 104 coupled to each rack 10. Heat exchanger 104 receives water at a first water temperature and transfers heat from the air to the water to cool the heated air to the first air temperature. The air at the first air temperature exits heat exchanger 104, wherein third vertical panel 110-3 and fourth vertical panel 110-4 prevent the air from flowing laterally and first vertical panel 110-1, top panel 112 and second vertical panel 110-2 ensure the air flows over the top of the row of racks 10 to the front of each rack 10 to repeat the cycle. The air from each rack 10 in the row of racks 10 may mix with air from other racks 10 in the row of racks 10.

### Modular Containment of Multiple Rows of Racks

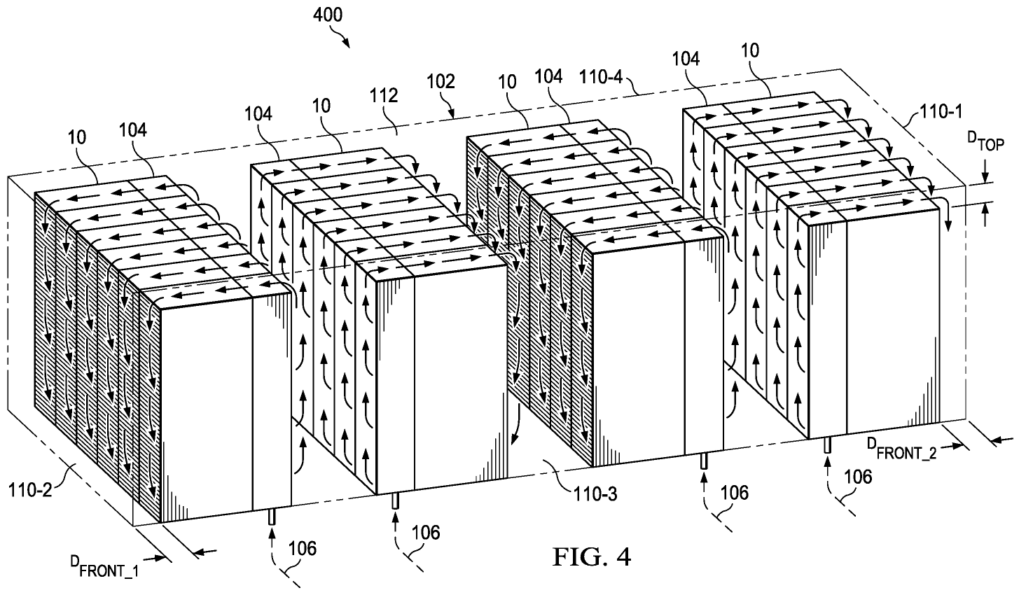

Turning to FIG. 4, a facility may have multiple rows of racks 10, each row containing multiple racks 10 and each rack 10 containing multiple information handling systems. In some embodiments, the facility may have an air conditioning system (not shown) for cooling room air to a room air temperature based on comfort of people working in the facility. Modular containment system 400 may be configured with a plurality of vertical panels 110-1 to 110-4 to thermally isolate multiple rows of racks 10 from the air conditioning system and direct air to flow over the top of the racks 10.

As depicted in FIG. 4, a first row of racks 10 may be oriented in a first direction and an adjacent second row of racks 10 may be oriented in a second direction opposite the first direction such that air exiting each rack 10 of the first row of racks 10 mixes with air exiting each rack 10 of the second row of racks 10. Also depicted in FIG. 4, a first row of racks 10 may be oriented in a first direction and an adjacent second row of racks 10 may be oriented in a second direction opposite the first direction such that air flows to the front of each rack 10 of the first row of racks 10 and the front of each rack 10 of the second row of racks 10.

First vertical panel 110-1 of the plurality of vertical panels 110 is positioned a first vertical panel separation distance (D_{FRONT_1}) from a front of a first row of racks 10, second vertical panel 110-2 of the plurality of vertical panels 110 is positioned a second vertical panel separation distance (D_{FRONT_2}) from the front of a second row of racks 10 and top panel 112 is positioned a top panel separation distance (D_{TOP}) above each rack 10. Third vertical panel 110-3 may be proximate a first side of each rack 10 on one end of each row of racks 10 being isolated. Fourth vertical panel 110-4 may be proximate a second side of each rack 10 on an opposite end of each row of racks 10 being isolated.

In this configuration, air at a first air temperature flows into the front of each rack 10, the air is heated to a second air temperature by information handling systems in each rack 10, the heated air exits each rack 10 and flows through heat exchanger 104. Heat exchanger 104 receives water at a first water temperature and transfers heat from the air to the water to cool the heated air to the first air temperature. The air at the first air temperature exits heat exchanger 104, wherein third vertical panel 110-3 and fourth vertical panel 110-4 prevent the air from flowing laterally around each row of racks 10 and first vertical panel 110-1, top panel 112 and second vertical panel 110-2 ensure the air flows over the top of each row of racks 10 to the front of each rack 10 to repeat the cycle.

### Channeling Air Flow Around One or More Sides of a Rack

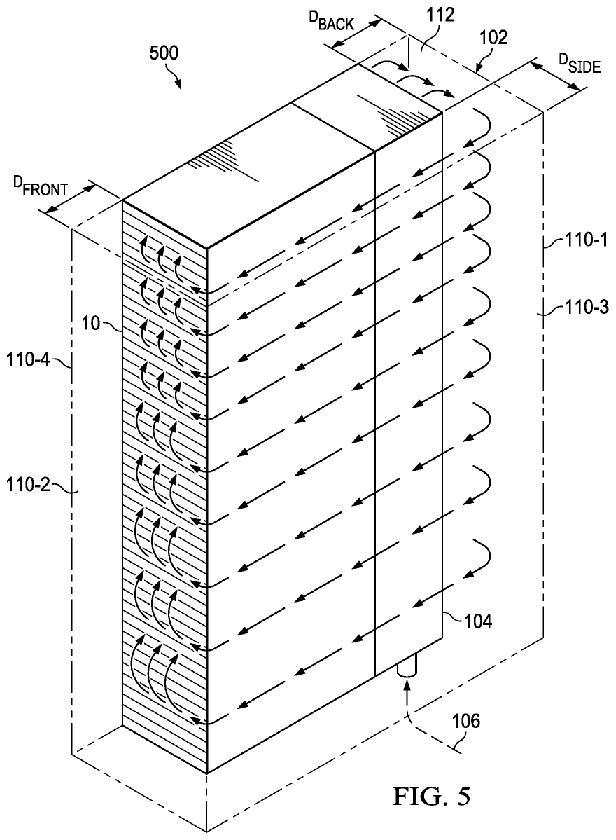

Turning to FIG. 5, a facility having a rack 10 containing multiple information handling systems may include modular containment system 500 for directing airflow around one or more sides of rack 10. In some embodiments, the facility may have an air conditioning system (not shown) for cooling room air to a room air temperature based on comfort of people working in the facility. Modular containment system 500 may be configured with a plurality of vertical panels 110-1 to 110-4 to thermally isolate a rack 10 and direct air to flow around the sides of rack 10. First vertical panel 110-1 of the plurality of vertical panels 110 is positioned a first vertical panel separation distance (D_{BACK}) from heat exchanger 104, second vertical panel 110-2 of the plurality of vertical panels 110 is positioned a second vertical panel separation distance (D_{FRONT}) from the front of rack 10 and top panel 112 is proximate a top surface of rack 10. Third vertical panel 110-3 and fourth vertical panel 110-4 are each coupled to first vertical panel 110-1 and second vertical panel 110-2 and top panel 112. One or more of third vertical panel 110-3 and fourth vertical panel 110-4 may be positioned a side separation distance (D_{SIDE}) from a side of rack 10, wherein the side separation distance is less than a width of rack 10. In this configuration, air at a first air temperature flows into the front of rack 10, the air is heated to a second air temperature by information handling systems in rack 10, the heated air exits rack 10 and flows through heat exchanger 104. Heat exchanger 104 receives water at a first water temperature and transfers heat from the air to the water to cool the heated air to the first air temperature. The air at the first air temperature exits heat exchanger 104, wherein top panel 112 proximate the top of rack 10 prevents the air from flowing over the top of rack 10 and first vertical panel 110-1, second vertical panel 110-2 and one or more of third vertical panel 110-3 and fourth vertical panel 110-4 ensure the air flows laterally around at least one side of rack 10 to the front of rack 10 to repeat the cycle.

### Channeling Air Flow Around the Sides of a Rack in a Row of Racks

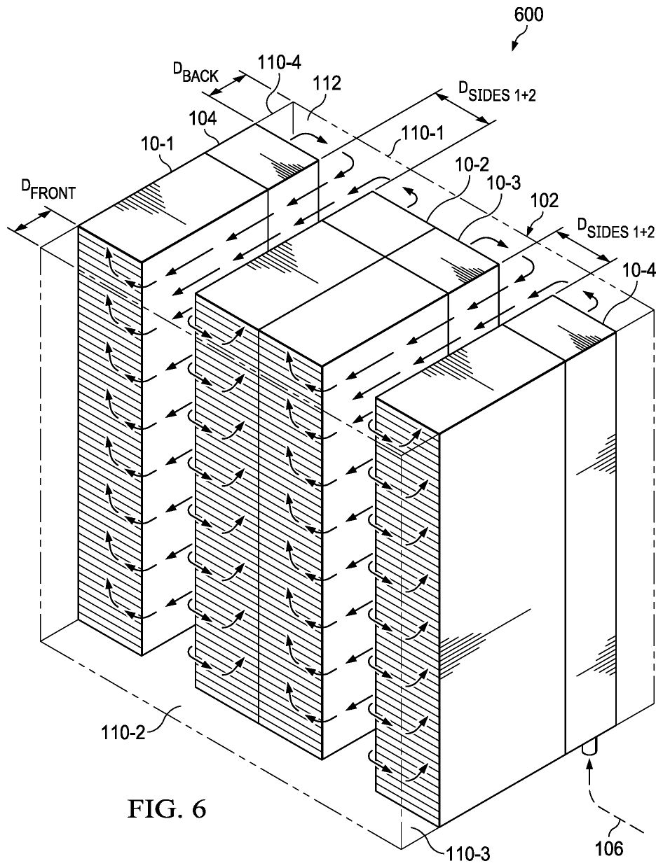

Turning to FIG. 6, a facility may have a row of racks 10 containing multiple information handling systems. In some embodiments, the facility may have an air conditioning system (not shown) for cooling room air to a room air temperature based on comfort of people working in the facility. Modular containment system 600 may be configured with a plurality of vertical panels 110-1 to 110-4 and top panel 112 to thermally isolate a row of racks 10 and direct air to flow around the sides of the racks 10, including between two adjacent racks 10. First vertical panel 110-1 of the plurality of vertical panels 110 is positioned a first vertical panel separation distance (D_{BACK}) from heat exchanger 104, second vertical panel 110-2 of the plurality of vertical panels 110 is positioned a second vertical panel separation distance (D_{FRONT}) from the front of rack 10 and top panel 112 is proximate a top surface of racks 10 to prevent air from flowing over the top of racks 10. Third vertical panel 110-3 and fourth vertical panel 110-4 are each coupled to first vertical panel 110-1 and second vertical panel 110-2 and top panel 112.

As depicted in FIG. 6, two adjacent racks 10 (e.g., rack 10-1 and rack 10-2) may be separated by a combined side separation distance (D_{SIDES1+2}), wherein the combined side separation distance between two adjacent racks 10 is less than a width of either rack 10. Third vertical panel 110-3 may be positioned proximate a first side of a rack 10 (e.g., rack 10-4) on a first end of the row of racks 10 and fourth vertical panel 110-4 may be positioned proximate a second side of a rack 10 (e.g., rack 10-1) on an opposite end of the row of racks 10. In this configuration, air at a first air temperature flows into the front of each rack 10, the air is heated to a second air temperature by information handling systems in each rack 10 and the heated air exits each rack 10 and flows through heat exchanger 104. Heat exchanger 104 receives water at a first water temperature that may be warmer than the first air temperature and transfers heat from the air to the water to cool the heated air to the first air temperature. The air at the first air temperature exits heat exchanger 104, wherein top panel 112 proximate the top of racks 10 prevents the air from flowing over the top of racks 10 and first vertical panel 110-1, second vertical panel 110-2 and one or more of third vertical panel 110-3 and fourth vertical panel 110-4 ensure the air flows between adjacent racks (e.g. racks 10-1 and 10-2 and racks 10-3 and 10-4) to the front of the row of racks 10 to repeat the cycle.

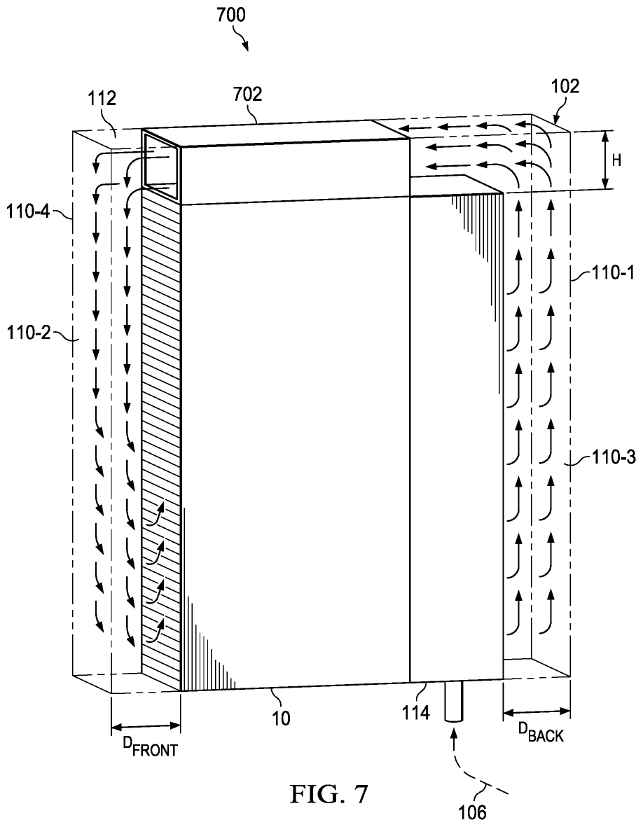

Turning to FIG. 7, a rack 10 containing multiple information handling systems may be configured such that air exiting heat exchanger 104 flows over the top of rack 10 but through a pass-through structure 702 on rack 10. In some embodiments, a facility may have an air conditioning system (not shown) for cooling room air to a room air temperature based on comfort of people working in the facility. Modular containment system 700 may be configured with a plurality of vertical panels 110-1 to 110-4 and top panel 112 to thermally isolate a rack 10 and direct air to flow through pass-through structure 702 on the top of rack 10. First vertical panel 110-1 of the plurality of vertical panels 110 is positioned a first vertical panel separation distance (D_{BACK}) from heat exchanger 104, second vertical panel 110-2 of the plurality of vertical panels 110 is positioned a second vertical panel separation distance (D_{FRONT}) from the front of rack 10 and top panel 112 is proximate pass-through structure 702 extending a height (H) above rack 10. Third vertical panel 110-3 and fourth vertical panel 110-4 are each coupled to first vertical panel 110-1 and second vertical panel 110-2 and top panel 112 and further proximate sides of rack 10. In this configuration, air at a first air temperature flows into the front of rack 10, the air is heated to a second air temperature by information handling systems in rack 10, the heated air exits rack 10 and flows through heat exchanger 104. Heat exchanger 104 receives water at a first water temperature and transfers heat from the air to the water to cool the heated air to the first air temperature. The air at the first air temperature exits heat exchanger 104, wherein third vertical panel 110-3 and fourth vertical panel 110-4 prevent the air from flowing laterally and first vertical panel 110-1, pass-through structure 702 and second vertical panel 110-2 ensure the air flows over the top of rack 10 to the front of rack 10 to repeat the cycle.

Any of the above modular containment systems may thermally isolate a single rack, a plurality of racks 10 in a row of racks 10 or a plurality of rows of racks 10.

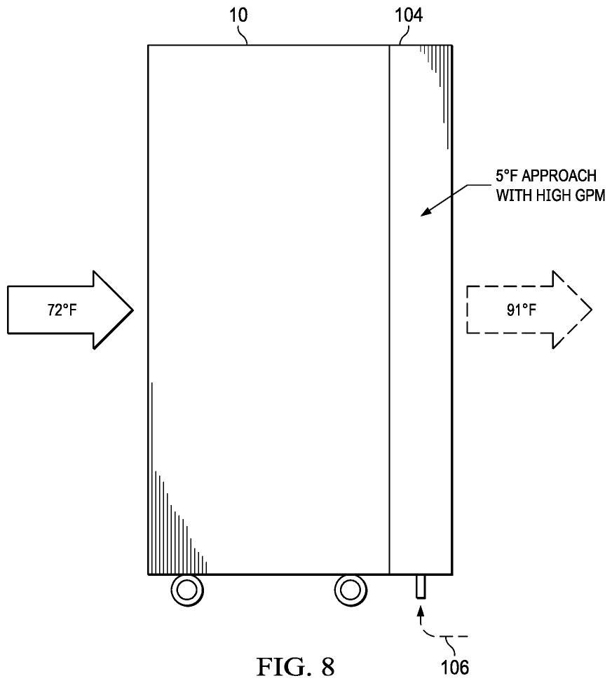

Embodiments overcome shortcomings of common approaches to cooling racks 10 of information handling systems. For example, FIG. 8 depicts a side view of a common approach to cooling racks 10 in which rack 10 is located in a facility and air exiting heat exchanger 104 at a second air temperature (e.g., 91 F) is allowed to mix with room air at a room air temperature (e.g., 72 F). In these situations, cooling the heated air to a room air temperature based on the comfort of people in the facility would require the air conditioning system cooling air at the second temperature (e.g., 91 F) to the first air temperature (e.g., 72 F). This approach does not capture all the heat generated by the information handling systems and water from a facility water feed (e.g., 86 F/30 C) may require a higher flow rate. Alternatively, water flowing into heat exchanger 104 may be chilled to a lower water temperature (e.g., 66 F/19 C) to remove more heat from the air before the air mixes with the room air. However, some heated air will still exit heat exchanger 104 at an air temperature greater than the first air temperature. In either case, the air conditioning system must compensate for the comfort of people in the facility and/or people in the facility must work at temperatures greater than 72 F.

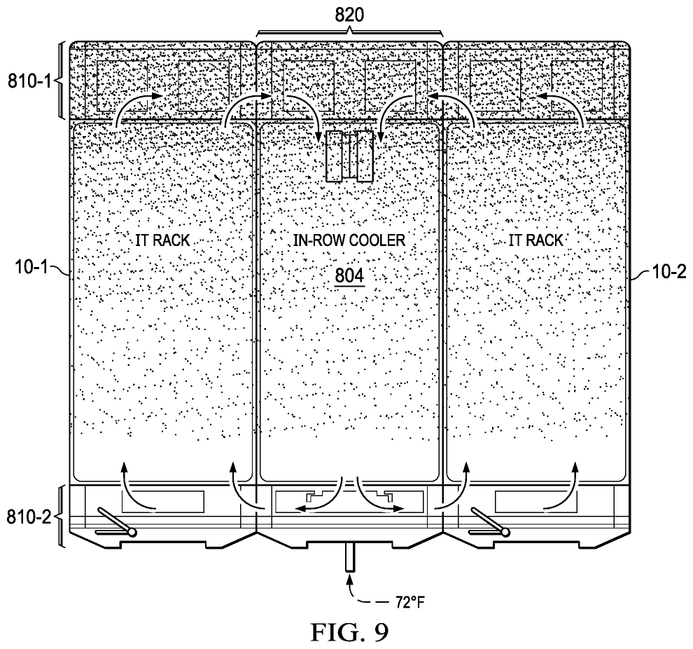

FIG. 9 depicts a top view of another common approach to cooling racks 10 in which an in-row cooler 804 having the same width 820 as racks 10 is positioned between two adjacent racks 10-1 and 10-2. Notably, space 810-1 lacks a heat exchanger (such as heat exchanger 104) coupled to each rack 10 such that two racks (e.g., racks 10-1 and 10-2) use the same heat exchanger 804. Using this approach, air at a second air temperature (e.g., 117 F) exits each rack 10-1 and 10-2 and circulates through the same heat exchanger 804 between two adjacent racks 10-1 and 10-2. Thus, if heat exchanger 804 is not functioning properly, two racks 10 are affected. Since the width 820 of an in-row cooler 804 must be accounted for between two adjacent racks 10, a row of racks 10 will require more in-row coolers 804 such that a row of racks 10 will have a lower rack density and a facility using this approach can fit fewer racks 10. Furthermore, space over the top of racks 10 is not utilized.

The above disclosed subject matter is to be considered illustrative, and not restrictive, and the appended claims are intended to cover all such modifications, enhancements, and other embodiments which fall within the true spirit and scope of the disclosure. Thus, to the maximum extent allowed by law, the scope of the disclosure is to be determined by the broadest permissible interpretation of the following claims and their equivalents, and shall not be restricted or limited by the foregoing detailed description.

What is claimed is:

1. A modular containment system for cooling information handling systems in a rack in a facility having an air conditioning system for cooling room air to a room air temperature, wherein air at a first air temperature greater than the room air temperature enters a front of the rack and the information handling systems heat the air to a second air temperature before the air exits a back of the rack, the modular containment system comprising:
a heat exchanger coupled to the back of the rack;
a plurality of vertical panels, wherein a first vertical panel of the plurality of vertical panels is positioned a first vertical panel separation distance from the heat exchanger and a second vertical panel of the plurality of vertical panels is positioned a second vertical panel separation distance from the front of the rack, and each vertical panel is coupled to an adjacent vertical panel to surround the rack;
a top panel coupled to each vertical panel of the plurality of vertical panels, wherein the top panel and the plurality of vertical panels thermally isolate the rack such that air in the modular containment system is prevented from mixing with the room air; and
a conduit coupled to the heat exchanger for supplying water at a first water temperature greater than the room air temperature;
wherein:
the heat exchanger is configured to transfer heat from the air that has been heated to the second air temperature by the plurality of information handling systems to the water such that the air is cooled to the first air temperature and the water is heated to a second water temperature; and
the plurality of vertical panels and the top panel are configured to channel all air exiting the heat exchanger to flow to the front of the rack.

2. The modular containment system of claim 1, wherein:
the top panel is separated from a top of the rack by a top panel separation distance;
a third vertical panel coupled to the top panel, the first vertical panel and the second vertical panel is proximate a first side of the rack; and
a fourth vertical panel coupled to the top panel, the first vertical panel and the second vertical panel is proximate a second side of the rack opposite the first side,
the third vertical panel and the fourth vertical panel prevent air from flowing around the rack; and
the first vertical panel, the second vertical panel and the top panel channel the air at the first air temperature over the top of the rack.

3. The modular containment system of claim 1, comprising a pass-through structure on top of the rack, wherein:
the top panel is proximate the pass-through structure;
a third vertical panel coupled to the top panel, the first vertical panel and the second vertical panel is proximate a first side of the rack; and
a fourth vertical panel coupled to the top panel, the first vertical panel and the second vertical panel is proximate a second side of the rack opposite the first side;
the third vertical panel and the fourth vertical panel prevent air from flowing around the rack; and
the first vertical panel, the second vertical panel and the top panel channel the air at the first air temperature through the pass-through structure.

4. The modular containment system of claim 1, wherein:
the top panel is proximate a top of the rack;
a third vertical panel coupled to the top panel, the first vertical panel and the second vertical panel is separated from a first side of the rack by a third vertical panel separation distance; and
a fourth vertical panel coupled to the top panel, the first vertical panel and the second vertical panel is separated from a second side of the rack opposite the first side by a third vertical panel separation distance;
the top panel prevents air from flowing over the top of the rack; and
the first vertical panel, the second vertical panel and one or more of the third vertical panel and the fourth vertical panel channel the air at the first air temperature around one or more of the first side and the second side of the rack.

5. The modular containment system of claim 1, further comprising a bottom panel coupled to each vertical panel of the plurality of vertical panels.

6. The modular containment system of claim 5, further comprising a set of supports coupled to the bottom panel.

7. A modular containment system for cooling information handling systems in a row of racks in a facility having an air conditioning system for cooling room air to a room air temperature, wherein air at a first air temperature greater than the room air temperature enters a front of each rack in the row of racks and the information handling systems heat the air to a second air temperature before the air exits a back of each rack, the modular containment system comprising:
a heat exchanger coupled to the back of each rack;
a top panel separated from a top of each rack in a row of racks;
a plurality of vertical panels, wherein a first vertical panel of the plurality of vertical panels is separated from the heat exchanger of each rack by a first vertical panel separation distance, a second vertical panel of the plurality of vertical panels is separated from a front of each rack by a second vertical panel separation distance, and each vertical panel is coupled to an adjacent vertical panel and the top panel to thermally isolate the row of racks such that air in the modular containment system is prevented from mixing with the room air; and
a conduit coupled to each heat exchanger for supplying water at a first water temperature greater than the room air temperature, wherein:
the heat exchanger is configured to transfer heat from the air that has been heated to the second air temperature by the plurality of information handling systems to the water such that the air is cooled to the first air temperature and the water is heated to a second water temperature; and
the plurality of vertical panels and the top panel are configured to channel all the air exiting each heat exchanger to the front of each rack in the row of racks.

8. The modular containment system of claim 7, wherein:
a third vertical panel is proximate a first side of a first rack in the row of racks;
a second rack is proximate the first rack;
a fourth vertical panel is proximate a second side of the second rack in the row of racks; and
the third vertical panel and the fourth vertical panel prevent air from flowing around the row of racks; and
the first vertical panel, the second vertical panel and the top panel channel the air at the first air temperature over the top of each rack in the row of racks.

9. The modular containment system of claim 7, wherein:
a third vertical panel is proximate a first side of a first rack in the row of racks;
a second rack adjacent the first rack is separated from the first rack by a rack separation distance between a second side of the first rack and a first side of the second rack;
a fourth vertical panel is proximate a second side of the second rack in the row of racks;
the top panel prevents air from flowing over the top of the row of racks; and
the first vertical panel, the second vertical panel and one or more of the third vertical panel and the fourth vertical panel channel the air at the first air temperature between two adjacent racks in the row of racks.

10. The modular containment system of claim 7, further comprising a bottom panel coupled to each vertical panel of the plurality of vertical panels.

11. The modular containment system of claim 10, further comprising a set of supports coupled to the bottom panel.

12. A facility comprising:
a facility cooling system for cooling room air to a room air temperature;
a facility water feed for supplying water at a first water temperature;
a plurality of racks in a row of racks, each rack containing a plurality of information handling systems, wherein a first row of racks of the plurality of rows of racks is oriented in a first direction and a second row of racks of the plurality of rows of racks is oriented in a second direction opposite the first direction such that air exiting each rack of the first row of racks mixes with air exiting each rack of the second row of racks; and
a modular containment system for cooling the plurality of information handling systems separately from the air conditioning system, wherein air at a first air temperature greater than the room air temperature enters a front of each rack in each row of racks and the information handling systems heat the air to a second air temperature before the air exits a back of each rack, the modular containment system comprising:
a heat exchanger coupled to the back of each rack;
a top panel separated from a top of each rack by a top panel separation distance;
a plurality of vertical panels coupled to the top panel, the plurality of vertical panels comprising:
a first vertical panel separated from a front of each rack in the first row of racks by the first vertical panel separation distance;
a second vertical panel separated from a front of each rack in the second row of racks by the second vertical panel separation distance;
a third vertical panel proximate a first side of a rack on an end of each row;
a fourth vertical panel proximate a second side of a rack on an opposite end of each row; and
a conduit coupled to each heat exchanger for supplying water received from the facility water feed at a first water temperature greater than the room air temperature, wherein
the heat exchanger is configured to transfer heat from the air that has been heated to the second air temperature by the plurality of information handling systems to the water such that the air is cooled to the first air temperature and the water is heated to a second water temperature; and
the third vertical panel and the fourth vertical panel are configured to prevent air from flowing around the plurality of racks; and
the first vertical panel, the second vertical panel and the top panel are configured to channel a first portion of the air exiting the heat exchanger in the first direction over the first row of racks and channel a second portion of the air exiting the heat exchanger in the second direction over the second row of racks.

13. The facility of claim 12, further comprising a bottom panel coupled to each vertical panel of the plurality of vertical panels.

14. The facility of claim 13, further comprising a set of supports coupled to the bottom panel.
